(19) United States
(12) Patent Application Publication
(10) Pub. No.: US 2025/0294942 A1
(43) Pub. Date: Sep. 18, 2025

(54) LIGHTING SYSTEM WITH LIGHT-EMITTING PIXEL COMPENSATION FOR A MOTOR VEHICLE

(71) Applicant: HELLA GMBH & CO. KGAA, Lippstadt (DE)

(72) Inventor: Martin Mügge, Geseke (DE)

(21) Appl. No.: 19/069,456

(22) Filed: Mar. 4, 2025

(30) Foreign Application Priority Data
Mar. 12, 2024 (DE) 102024107050.1

(51) Int. Cl. H10H 29/24; F21S 41/153; F21S 43/14; F21Y 115/10; H10H 29/80; H10H 29/856

(52) U.S. Cl. CPC H10H 29/24; F21S 41/153; F21S 43/14; H10H 29/856; H10H 29/882; F21Y 2115/10

(57) ABSTRACT

The invention relates to a lighting system for a motor vehicle. The lighting system includes a first lighting device with a plurality of separately controllable first light-emitting pixels and two second lighting devices, each of which can be arranged laterally on the first lighting device and each of which has a plurality of separately controllable second light-emitting pixels. According to the invention, at least one light-emitting pixel of the second light-emitting pixels has a second pixel size that is larger than the first pixel size of at least one light-emitting pixel of the first light-emitting pixels. The invention also relates to a motor vehicle.

### CROSS-REFERENCE TO RELATED APPLICATIONS

The present application claims the benefit of German Patent Application No. 10-2024-107-050.1, filed Mar. 12, 2024, the disclosure of which is incorporated by reference.

### FIELD OF THE INVENTION

The invention relates to a lighting system for a motor vehicle and a motor vehicle.

### BACKGROUND OF THE INVENTION

The embodiment of a pixelated or segmented functional surface of a light or lighting device on a motor vehicle is used to define and provide a desired lighting signature or to display additional information content (e.g. numbers, texts, pictograms) by means of different, individual switching of individual light-emitting pixels. This means that new content or light signatures can be developed over the service life of the motor vehicle and offered to the vehicle owner/driver without having to develop a new light each time. A corresponding lighting device is known from DE 10-2016-119-326 A1.

Displays with light-emitting diodes are known from the general prior art, which are also known as “LED displays” or “LED panels”. The LED displays have a matrix arrangement of RGB LEDs, which are primarily known from advertising or as video walls at trade fairs and concerts. The RGB LEDs have a very low luminous flux, which is why these LED displays cannot be used in the automotive field to achieve the legally required luminous intensity with a correspondingly limited number of LEDs. In addition, such LED displays are usually controlled via video interfaces, such as HDMI, which are not used in motor vehicles, in particular as such video signals are not or are only insufficiently suitable for controlling lights and functions. An additional disadvantage of these LED displays is the pixelated arrangement of light-emitting diodes in a matrix. The observer sees a bright dot at each LED point and only due to the very close spacing and correspondingly high resolution is a sharp image recognizable for an observer even from close viewing distances. For this reason, distances of less than 2 mm between adjacent light-emitting diodes are already provided for such LED panels, or distances of 1 mm or less are being aimed for.

In order to produce the legally required minimum luminous intensities of 4 cd for a red tail light, 50 cd (ECE) or 130 cd (SAE) for an amber turn signal and 60 cd (ECE) or 80 cd (SAE) for a red brake light, as well as 400 cd (ECE) or 500 cd (SAE) for a white daytime running light in automotive applications, light-emitting diodes with higher operating currents and luminous fluxes, as well as an automotive specification, must be used and optical systems that make optimum use of the luminous flux of the light-emitting diodes so that a brake light or a turn signal can be generated even with a small number of light-emitting pixels and accordingly different light signatures can be developed and permitted with the existing segmented matrix display surface.

In the case of lighting systems with a matrix display surface that extend over the entire width of a motor vehicle, a one-piece design is impractical due to more difficult assembly conditions, manufacturing tolerances and an increased risk of damage, so that such lighting systems usually have a central first lighting device, on each side of which a second lighting device of the lighting system is arranged. In the case of a lighting system arranged at the vehicle rear, the first lighting device can be arranged on a trunk lid, for example. In the case of a lighting system arranged on a vehicle front, the first lighting device can be arranged on a radiator grille, for example. The second lighting devices are preferably attached to the side of the first lighting device on the body of the motor vehicle.

If a communication matrix (CMX) is to be integrated into such a three-part lighting system with simultaneous fulfillment of signal functions, such as tail light, brake light, reversing light or similar, and is to be designed as a continuous CMX light strip in the outer lights and also in the central light, installation space problems for the integration of the light-emitting pixels may arise due to the curvature of the outer second lighting devices required for an adaption to the body.

If, for example, a grid of light-emitting pixels of the central first lighting device is continued in the outer second lighting devices, the grid in the second lighting devices can contract towards the outside due to the curved surface profile. The pixels become smaller and the situation may arise where the size becomes too small to implement the optical system and equip each pixel with the LED light source. Depending on the pixel size, an RGB LED or two separate LEDs with different colors, e.g. red and yellow or white and yellow, can also be provided, for which a pixel size then reaches the limit even faster, where integration of the LEDs is no longer possible.

### SUMMARY OF THE INVENTION

It is therefore the object of the invention to provide a lighting system for a motor vehicle which is improved compared to the prior art and which has an improved integration of the light-emitting pixels. Further, the lighting system preferably has a cost-effective and compact design.

The above object is achieved by embodiments of the present invention. In particular, the object is achieved by a lighting system and a motor vehicle as set forth herein. Features and details that are disclosed in connection with the lighting system according to the invention naturally also apply in connection with the motor vehicle according to the invention and vice versa, so that reference is or can always be made reciprocally regarding the disclosure of the individual aspects of the invention.

According to a first aspect of the invention, the object is achieved by a lighting system for a motor vehicle. The lighting system has a first lighting device with a plurality of separately controllable first light-emitting pixels and two second lighting devices, each of which can be arranged laterally on the first lighting device and each of which has a plurality of separately controllable second light-emitting pixels. According to the invention, at least one light-emitting pixel of the second light-emitting pixels has a second pixel size that is larger than the first pixel size of at least one light-emitting pixel of the first light-emitting pixels.

The lighting system according to the invention thus has three lighting devices which can be arranged next to one another, optionally at the same height on a vehicle front or a vehicle rear of the motor vehicle. The first lighting device is thus designed as the middle one of the three lighting devices, which can be arranged between the two second lighting devices, forming a separating joint.

According to the invention, further first lighting devices can also be provided, which can be arranged adjacent to one another, so that the group of first lighting devices can be arranged between the second lighting devices. Additionally or alternatively, a plurality of second lighting devices, for example a total of four second lighting devices, can also be provided, which can be arranged as groups each laterally next to the first lighting device or the group of first lighting devices.

The first lighting device and the second lighting devices are optionally operable via a common control device of the lighting system. The first light-emitting pixels are optionally designed to be separately controllable by the control device, preferably such that a light intensity and/or light color of the individual first light-emitting pixels can be selectively adjusted. The second light-emitting pixels are optionally designed to be separately controllable by the control device, preferably such that a light intensity and/or light color of the individual second light-emitting pixels can be selectively adjusted. First illuminants of the first light-emitting pixels are optionally arranged on a first printed circuit board of the first lighting device. Second illuminants of the second light-emitting pixels are optionally arranged on a second printed circuit board of the second lighting devices. According to the invention, the first light-emitting pixels and/or the second light-emitting pixels can have further optical elements for manipulating the produced light. The first light-emitting pixels and the second light-emitting pixels provide a communication matrix for creating a defined light signature. The light signature can be generated by selectively controlling the first light-emitting pixels and the second light-emitting pixels.

The light-emitting pixels each have a pixel size. This means that at least some of the first light-emitting pixels have the first pixel size. In the context of the invention, the first pixel size is understood to be a predefined pixel size of a first pixel of a first grid of the first lighting device. At least some of the second light-emitting pixels have the second pixel size. In the context of the invention, the second pixel size is understood to be a predefined pixel size of a second pixel of a second grid of the second lighting device.

Optionally, at least 50%, in particular at least 90%, and particularly 100% of the first light-emitting pixels have the first pixel size. It is further preferred that more than 50%, in particular at least 80%, of the second light-emitting pixels have the second pixel size. According to the invention, the second pixel size is larger than the first pixel size. The larger design of the second pixel size of the second pixels counteracts the effect of the second grid of the second light-emitting pixels of the second lighting devices contracting in relation to the first grid of the first light-emitting pixels. Thus it can be ensured that there is sufficient space in the second lighting device for an optical system that is arranged in the first lighting device, so that the same optical system can be extended over the first lighting device and the second lighting devices. Thus, for example, an optical system can be used for the entire lighting system according to the invention, i.e. for the first lighting device and the second lighting devices, in which a plurality of illuminants and/or space-consuming reflector devices or similar are provided for each lighting pixel.

A lighting system according to the invention has the advantage over conventional lighting systems that an improved communication matrix function (CMX function) is provided with simple means and in a cost-effective manner, which has a lower distortion in lateral areas of the lighting system and/or has a uniform optical system. This prevents, for example, the second lighting devices from having a different illuminant size, for example mini-LED, micro-LED or similar, than the first lighting device, which has larger LEDs, for example. Likewise, a change in the technology of the illuminants between the first lighting device and the second lighting devices is advantageously avoided.

According to another embodiment of the invention, it can be provided in a lighting system that a second light-emitting pixel height of at least one light-emitting pixel of the second light-emitting pixels is at least twice as large as a first light-emitting pixel height of at least one light-emitting pixel of the first light-emitting pixels. Accordingly, it is preferred according to the invention that the second light-emitting pixel height of the second light-emitting pixel corresponds to two first light-emitting pixel heights of two first light-emitting pixels arranged one above the other and combined to form a light-emitting pixel. Doubling the light-emitting pixel height of the second light-emitting pixel provides more installation space for the optical system in the second lighting device. It may also be provided that the second light-emitting pixel height corresponds to 3 or 4 times the first light-emitting pixel height. According to the invention, the second light-emitting pixel height can also correspond to a non-integer multiple of the first light-emitting pixel height, for example 1.5 times, 2.3 times or similar. Optionally this applies to at least 50%, in particular at least 90%, or particularly 100% of the second light-emitting pixels. This has the advantage of further improving an integrability of a single optical system within the lighting system according to the invention with simple means and in a cost-effective manner.

According to the invention, it is possible that a second light-emitting pixel width of at least one light-emitting pixel of the second light-emitting pixels is at least twice as large as a first light-emitting pixel width of at least one light-emitting pixel of the first light-emitting pixels. Accordingly, the second light-emitting pixel width of the second light-emitting pixel corresponds to two first light-emitting pixel widths of two first light-emitting pixels arranged next to one another and combined to form a light-emitting pixel. Doubling the light-emitting pixel width of the second light-emitting pixel provides more installation space for the optical system in the second lighting device. It may also be provided that the second light-emitting pixel width corresponds to 3 or 4 times the first light-emitting pixel width. According to the invention, the second light-emitting pixel width can also correspond to a non-integer multiple of the first light-emitting pixel width, for example 1.5 times, 2.3 times or similar. Optionally this applies to at least 50%, in particular at least 90%, or particularly 100% of the second light-emitting pixels. This has the advantage of further improving the integrability of a single optical system within the lighting system according to the invention with simple means and in a cost-effective manner.

Further optionally, the second light-emitting pixels have at least partially different light-emitting pixel heights and/or light-emitting pixel widths. Accordingly, for example, some of the second light-emitting pixels may have the second light-emitting pixel height and the smaller first light-emitting pixel width and/or some of the second light-emitting pixels may have the first light-emitting pixel height and the larger second light-emitting pixel width and/or some of the second light-emitting pixels may have the first light-emitting pixel height and the first light-emitting pixel width and/or a further part of the second light-emitting pixels may have the second light-emitting pixel height and the second light-emitting pixel width. Here, various combinations are conceivable according to the invention. This has the advantage of further improving the integrability of a single optical system within the lighting system according to the invention with simple means and in a cost-effective manner.

In another embodiment of the invention, a lighting system may provide that more than 50% of the first light-emitting pixels have the first pixel size. Optionally, more than 90% of the first light-emitting pixels have the first pixel size. In particular, 100% of the first light-emitting pixels have the first pixel size. Here, it is preferred that the first pixel size is defined by the first pixel width and the first pixel height. A high proportion of first light-emitting pixels with the first pixel size is advantageous in particular in the case of a first lighting device designed to be relatively flat or plate-shaped, as the flat or plate-shaped design means that there are no installation space problems and thus a particularly homogeneous first grid can be provided. This has the advantage that a particularly homogeneous appearance of the communication matrix of the first lighting device is provided with simple means and in a cost-effective manner.

Optionally, at least one light-emitting pixel of the second light-emitting pixel has the first pixel size. Here, it is preferred that the light-emitting pixel has the first pixel width and the first pixel height. Optionally, between 10% and 50% of the second light-emitting pixels have the first pixel size. The second light-emitting pixels, which have the first pixel size, are optionally arranged in an area of the second lighting device which is designed to be particularly flat or plate-shaped. This can be, for example, an area arranged directly adjacent to the first lighting device. Further, this can be an area of the second lighting device that is arranged furthest away from the first lighting device. This has the advantage that a particularly homogeneous appearance of the communication matrix of the second lighting device is provided with simple means and in a cost-effective manner.

According to another embodiment of the invention, it may be provided in a lighting system that at least one light-emitting pixel of the first light-emitting pixels has a third pixel size, wherein the third pixel size is larger than the first pixel size. Here, it may be provided according to the invention that the third pixel size corresponds or at least substantially corresponds to the second pixel size. The first light-emitting pixel can, for example, have the first pixel height or the first pixel width. The third pixel size is preferably smaller than the second pixel size. The first light-emitting pixel with the third pixel size is preferably arranged in a lateral edge area of the first light-emitting device and thus adjacent to a lighting device of the second lighting devices. Optionally, the first light-emitting pixel with the third pixel size is arranged in an area of the first light-emitting device which has a greater curvature than another area of the first lighting device. This has the advantage of further improving the integrability of a single optical system within the lighting system according to the invention with simple means and in a cost-effective manner.

The second pixel size is optionally at least four times the first pixel size. In particular, the second pixels with the second pixel size have the second pixel width and the second pixel height, with the second pixel width being twice as large as the first pixel width and the second pixel height being twice as large as the first pixel height. This has the advantage of further improving the integrability of a single optical system within the lighting system according to the invention with simple means and in a cost-effective manner.

According to the invention, it is preferred that the first lighting device has a first emitting surface curved by a maximum of 20° about a vertical axis. The first emitting surface is understood to be a surface of the first lighting device via which light from the first lighting device can be emitted to an environment of the motor vehicle. A light signature of the communication matrix of the first lighting device can therefore be emitted to the environment via the first emitting surface. Preferably, the curvature of the first emitting surface is a maximum of 15° and more preferably a maximum of 10°. The lower the curvature of the emitting surface, the more uniform is the available installation space for the first illuminants of the first light-emitting pixels. This has the advantage that a particularly homogeneous appearance of the communication matrix of the first lighting device is provided with simple means and in a cost-effective manner.

Optionally, the second lighting devices each have a second emitting surface curved by at least 20° about a vertical axis. According to the invention, the curved second emitting surface can extend up to larger angles of 45° to 80° about the vertical axis. The second emitting surface is understood to be a surface of the second lighting device via which light from the second lighting device can be emitted to an environment of the motor vehicle. A light signature of the communication matrix of the second lighting device can therefore be emitted to the environment via the second emitting surface. Preferably, the curvature of the second emitting surface is at least 60° and further preferably at least 80°. Such lighting devices are particularly designed for arrangement at the front or rear edge areas of the body of the motor vehicle. Thus, by means of each of the second lighting devices, light or a light signature can be emitted from two adjacent sides of the motor vehicle into the environment of the motor vehicle. This has the advantage of further improving the integrability of a single optical system within the lighting system according to the invention with simple means and in a cost-effective manner.

The first light-emitting pixels and/or second light-emitting pixels optionally each have at least one reflector element, at least one light-emitting diode, and at least one light-transmitting optical layer.

The reflector element is designed to reflect and preferably limit the light emitted by the light-emitting diodes. For this purpose, the reflector element is preferably divided into a plurality of segments, with at least one light-emitting diode being arranged in one segment. According to the invention, two or more than two light-emitting diodes can also be arranged in one segment. For example, the light-emitting diodes can be designed as conventional LEDs, mini-LEDs or micro-LEDs. The LEDs are preferably arranged on a printed circuit board, for example as surface mount device (SMD) LEDs. The optical layer is designed to transmit the light emitted by the light-emitting diodes and the light reflected by the reflector element of the light-emitting diodes.

The optical layer is optionally designed to achieve an optical effect, such as focusing the light and/or scattering and homogenizing the light and/or deflecting the light or similar. For example, it can be provided that the optical layer has optical scattering elements on its front and/or rear side. As optical scattering elements can be provided pillow optics or micro-optics, for example, or a diffractive diffuser structure or microstructure or, in the simplest case, an eroded structure or etched structure.

Optionally, the optical layer is designed as an optically segmented optical layer, with the segmentation being preferably adapted to the light-emitting pixels defined by the reflector element. The optical layer thus preferably extends over a plurality of or preferably all of the first light-emitting pixels or second light-emitting pixels. Further preferably, the segmentation of the optical layer is adapted to the position of the light-emitting diodes in relation to the optical layer. Particularly preferably, the optical layer is designed to achieve the most uniform light emission distribution possible for a light-emitting pixel, so that the light-emitting pixel can be perceived by an observer as a homogeneous light source. Accordingly, the optical layer is preferably designed such that the observer of the light-emitting pixel cannot see how many light-emitting diodes which emit light are arranged in the light-emitting pixel. It is particularly preferred for the optical layer to have such a design for a majority of the light-emitting pixels or for all light-emitting pixels. The optical layer can also have a coloration, either to produce a lower transmission factor or to provide a defined color impression. Furthermore, the optical layer can have a coating on the front side, for example a sputtering, to create a mirror effect with transmission remaining for the lighting device. This has the advantage that the lighting system according to the invention has an optical system which can be integrated particularly advantageously within the lighting system.

Further optionally, the first light-emitting pixels and/or the second light-emitting pixels at least partially have a plurality of light-emitting diodes with different colors. In the context of the invention, this is understood to mean that the light-emitting diodes are designed to emit light with wavelengths different from one another. A first light-emitting diode can, for example, be designed to emit light with a first wavelength, and a second light-emitting diode can, for example, be designed to emit light with a second wavelength that is different from the first wavelength. Preferably, at least one first light-emitting diode of the light-emitting diodes is designed as a white light-emitting diode. Further preferably, at least one second light-emitting diode is designed as a red light-emitting diode. Further preferably, at least one third light-emitting diode is designed as a yellow light-emitting diode. Alternatively or additionally, one or more light-emitting diodes can be designed as multicolored light-emitting diodes. In the context of the invention, a multicolored light-emitting diode is understood to be a light-emitting diode which is designed to emit light over a spectrum of different wavelengths. A multicolored light-emitting diode can therefore be used to emit light in different colors alternately in a targeted manner. For example, in a light-emitting pixel, one light-emitting diode can be designed as a multicolored light-emitting diode and another light-emitting diode can be designed as a white light-emitting diode. The individual switchability of the light-emitting diodes in a segment thus allows the light emission colors of the individual light-emitting pixels to be selectively influenced. The light-emitting diodes are preferably arranged close together in order to take up as little installation space as possible. Further, the effect of a single light source within a light-emitting pixel can thus be achieved. This has the advantage that a particularly versatile communication matrix with a plurality of different display options is provided with simple means and in a cost-effective manner.

In another embodiment the optical layer has a diffuser film or a diffuser plate. A diffuser film is understood to be a layer that can be spanned in front of the reflector element, for example on the reflector element, a housing of the first lighting device or second lighting device, a subframe or similar. Here, it is preferred for the diffuser film to have a relatively high degree of flexibility or elasticity. Preferably, the diffuser film has a diffuser structure and/or micro-optics or similar. The diffuser film has a substantially thinner wall thickness, preferably less than 1.2 mm, in particular less than 0.5 mm, than conventional optical disks, which usually have a wall thickness of more than 2 mm. Preferably, the wall thickness of the diffuser film is at least 0.2 mm. Light conduction effects, which are particularly pronounced within a relatively thick optical disk and impair the contrast between active light-emitting pixels and adjacent inactive light-emitting pixels, can be significantly reduced or substantially avoided by the diffuser film. Consequently, a better contrast ratio can be achieved with the diffuser film and thus an improved, sharper display can be provided for an observer of the lighting system.

Optionally, the optical layer has a plurality of diffuser films or diffuser plates arranged one above the other. The diffuser films or diffuser plates preferably have complementary diffuser structures and/or micro-optics or similar. In this context, two diffuser films arranged one above the other are preferred. Alternatively, according to the invention, three or more diffuser films or diffuser plates arranged one above the other can also be provided. Preferably, the diffuser films or diffuser plates arranged one above the other have different wall thicknesses. A lower first diffuser film, for example designed as a carrier film, can have a greater wall thickness than a second diffuser film arranged thereon, for example in order to provide a basic stability. Alternatively or additionally, the diffuser films or diffuser plates can also have different materials and/or textures or similar. Thus the overall wall thickness of the optical layer can be advantageously reduced while ensuring sufficient strength.

The optical layer optionally has a wall thickness of between 0.1 mm and 1.2 mm. Particularly preferably, the optical layer has a wall thickness of between 0.1 mm and 0.5 mm. In the case of two diffuser films arranged one above the other, a first diffuser film preferably has a wall thickness of between 0.1 mm and 0.5 mm and a second diffuser film has a wall thickness of between 0.1 mm and 0.25 mm. Such low wall thicknesses allow light conduction effects to be further reduced. In this manner, an improved contrast ratio can be achieved and thus an improved, sharper display can be provided for an observer of the lighting system. As an alternative to diffuser films, thin-walled, injection-molded optical disks with wall thicknesses between 0.5 mm and 1.2 mm can also be used.

According to a second aspect of the invention, the object is achieved by a motor vehicle. The motor vehicle has a vehicle front and a vehicle rear. A lighting system according to the invention is arranged on the vehicle front and/or the vehicle rear, wherein the first lighting device extends over at least a partial area of the vehicle front and/or the vehicle rear and the second lighting devices are each arranged on one side of the first lighting device and each extend over partial areas of two vehicle sides of the motor vehicle.

Accordingly, the motor vehicle may have a lighting system according to the invention, for example at the vehicle front. When arranged at the vehicle front, the first lighting device is preferably arranged centrally on a radiator grille, a hood or similar and preferably extends over a predominant part of the vehicle front width of the vehicle front. The second lighting devices are arranged to the side of the first lighting device in such a manner that part of the second lighting devices is directed towards an area in front of the motor vehicle in the direction of travel and part of the second lighting device is directed towards an area to the side of the motor vehicle. The second lighting devices are preferably each arranged at and attached to a front edge area of the body.

Alternatively and additionally, the motor vehicle may have a lighting system according to the invention, for example at the vehicle rear. When arranged at the vehicle rear, the first lighting device is preferably arranged centrally on a trunk lid, a bumper or similar and preferably extends over a predominant part of the vehicle rear width of the vehicle rear. The second lighting devices are arranged to the side of the first lighting device in such a manner that part of the second lighting devices is directed towards an area behind the motor vehicle in the direction of travel and part of the second lighting device is directed towards an area to the side of the motor vehicle. The second lighting devices are preferably each arranged at and attached to a rear edge area of the body.

The motor vehicle according to the invention offers all the advantages which have already been described for a lighting system according to the first aspect of the invention. Accordingly, the motor vehicle according to the invention has the advantage over conventional motor vehicles that an improved communication matrix function (CMX function) is provided with simple means and in a cost-effective manner, which has less distortion in lateral areas of the lighting system and/or has a uniform optical system. This prevents, for example, the second lighting devices from having a different illuminant size, for example mini-LED, micro-LED or similar, than the first lighting device, which has larger LEDs, for example. Likewise, a change in the technology of the illuminants between the first lighting device and the second lighting devices is advantageously avoided.

### BRIEF DESCRIPTION OF THE DRAWINGS

The invention is explained in more detail below with reference to the accompanying schematic drawings. All features arising from the claims, the description or the figures, including design details, can be substantial to the invention both individually and in any of the various combinations. In the figures:

FIG. 1 is a top view of a lighting system according to the prior art;

FIG. 2 is a top view of a lighting system according to a preferred first exemplary embodiment of the invention;

FIG. 3 is a top view of a lighting system according to a preferred second exemplary embodiment of the invention;

FIG. 4 is a top view of a lighting system according to a preferred third exemplary embodiment of the invention;

FIG. 5 is a top view of a lighting system according to a preferred fourth exemplary embodiment of the invention;

FIG. 6 is a top view of a lighting system according to a preferred fifth exemplary embodiment of the invention;

FIG. 7 is a perspective view of a first lighting device according to a preferred exemplary embodiment of the invention;

FIG. 8 is an exploded view of the first lighting device from FIG. 7; and

FIG. 9 is a rear view of a motor vehicle according to an exemplary embodiment of the invention.

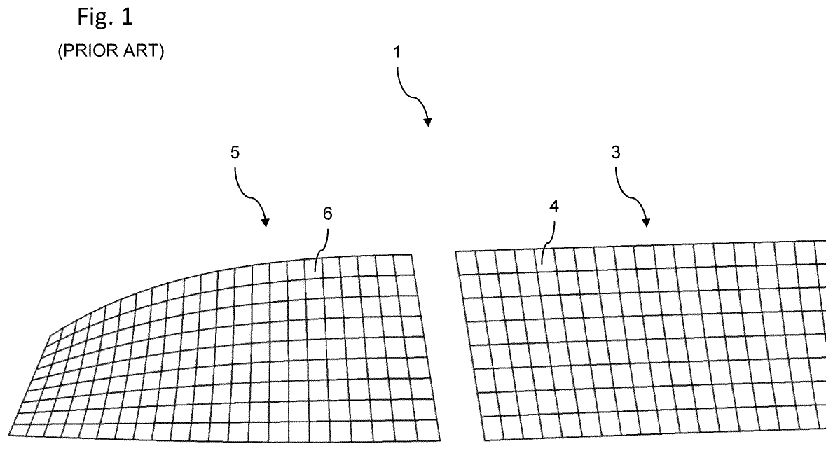

Similar or identical elements are provided with the same reference signs in FIGS. 1 to 9. Therein, for the sake of clarity, similar or identical elements are not all provided with a reference sign throughout.

### DETAILED DESCRIPTION OF THE CURRENT EMBODIMENTS

FIG. 1 shows a schematic top view of a lighting system 1 according to the prior art. The lighting system 1 has a first lighting device 3 with a plurality of first light-emitting pixels 4 and a second lighting device 5 with a plurality of second light-emitting pixels 6. The first light-emitting pixels 4 and the second light-emitting pixels 6 are each arranged in a grid which extends over the entire lighting system 1. The first light-emitting pixels 4 have a light-emitting pixel size that corresponds to a light-emitting pixel size of the second light-emitting pixels 6. The first light-emitting pixels 4 and the second light-emitting pixels 6 have a rectangular or square design. A curvature of the second lighting device 5 about a vertical axis causes a distortion of the grid of the second lighting device 5. This results in installation space problems for the optical system used.

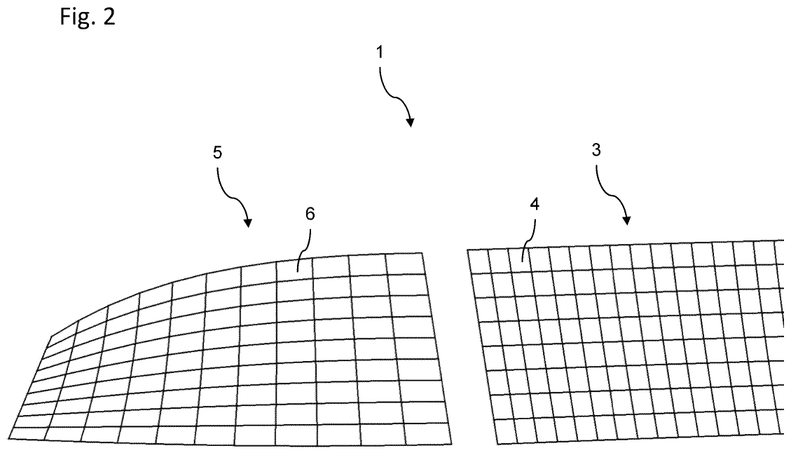

In FIG. 2, a lighting system 1 according to a first exemplary embodiment of the invention is shown schematically in a top view. The lighting system 1 has a first lighting device 3 with a plurality of first light-emitting pixels 4 and a second lighting device 5 with a plurality of second light-emitting pixels 6. The first light-emitting pixels 4 and the second light-emitting pixels 6 are each arranged in a grid. The second lighting device 5 also has a curvature about the vertical axis. The first light-emitting pixels 4 have a first light-emitting pixel size that is smaller than a second light-emitting pixel size of the second light-emitting pixels 6. In this exemplary embodiment, the second light-emitting pixels 6 have a second light-emitting pixel width that is twice as large as a first light-emitting pixel width of the first light-emitting pixels 4. The light-emitting pixel height of the first light-emitting pixels 4 corresponds to the light-emitting pixel height of the second light-emitting pixels 6. The first light-emitting pixels 4 have a rectangular or square design. The second light-emitting pixels 6 have a rectangular design. Thus installation space problems for the optical system used are prevented.

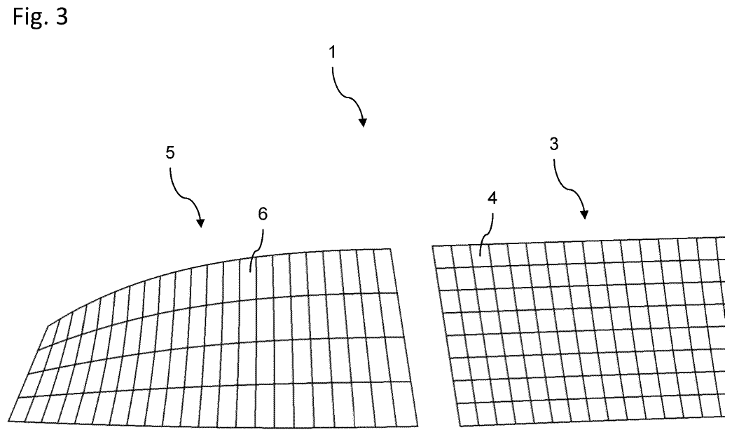

FIG. 3 shows a lighting system 1 according to a second exemplary embodiment of the invention schematically in a top view. The lighting system 1 has a first lighting device 3 with a plurality of first light-emitting pixels 4 and a second lighting device 5 with a plurality of second light-emitting pixels 6. The first light-emitting pixels 4 and the second light-emitting pixels 6 are each arranged in a grid. The second lighting device 5 also has a curvature about the vertical axis. The first light-emitting pixels 4 have a first light-emitting pixel size that is smaller than a second light-emitting pixel size of the second light-emitting pixels 6. In this exemplary embodiment, the second light-emitting pixels 6 have a second light-emitting pixel height that is twice as large as a first light-emitting pixel height of the first light-emitting pixels 4. The light-emitting pixel width of the first light-emitting pixels 4 corresponds to the light-emitting pixel width of the second light-emitting pixel 6. The first light-emitting pixels 4 have a rectangular or square design. The second light-emitting pixels 6 have a rectangular design. Thus installation space problems for the optical system used are prevented as well.

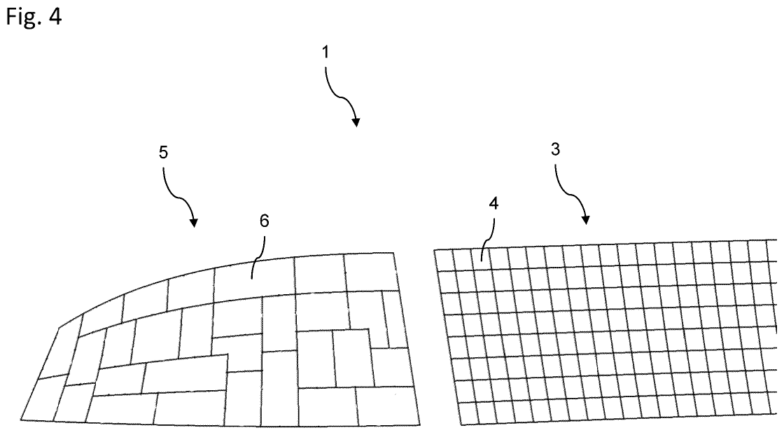

In FIG. 4, a lighting system 1 according to a third exemplary embodiment of the invention is shown schematically in a top view. The lighting system 1 has a first lighting device 3 with a plurality of first light-emitting pixels 4 and a second lighting device 5 with a plurality of second light-emitting pixels 6. The first light-emitting pixels 4 and the second light-emitting pixels 6 are each arranged in a grid. The second lighting device 5 also has a curvature about the vertical axis. The first light-emitting pixels 4 have a first light-emitting pixel size that is smaller than a second light-emitting pixel size of the second light-emitting pixels 6, wherein the second light-emitting pixels 6 have different light-emitting pixel sizes in this exemplary embodiment. The first light-emitting pixels 4 have a rectangular or square design. The second light-emitting pixels 6 partly have a rectangular design and partly have other angular shapes with parallel sides. Thus installation space problems for the optical system used are prevented as well.

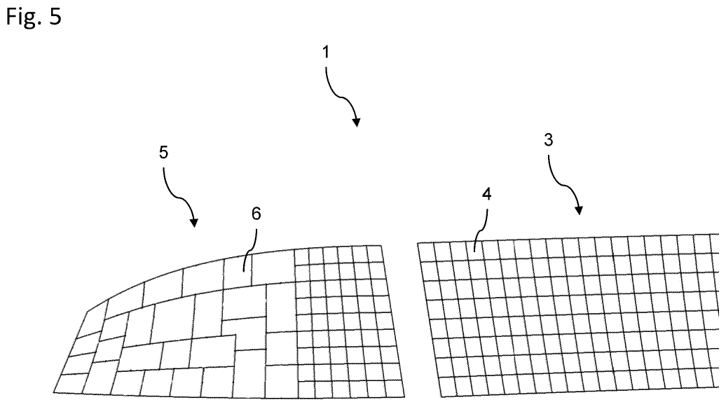

FIG. 5 shows a lighting system 1 according to a fourth exemplary embodiment of the invention schematically in a top view. The lighting system 1 has a first lighting device 3 with a plurality of first light-emitting pixels 4 and a second lighting device 5 with a plurality of second light-emitting pixels 6. The first light-emitting pixels 4 and the second light-emitting pixels 6 are each arranged in a grid. The second lighting device 5 also has a curvature about the vertical axis. The first light-emitting pixels 4 have a first light-emitting pixel size that is smaller than a second light-emitting pixel size of the second light-emitting pixels 6. In this exemplary embodiment, the second light-emitting pixels 6 have different light-emitting pixel sizes, wherein some light-emitting pixels of the second light-emitting pixels 6 have the first light-emitting pixel size and other light-emitting pixels of the second light-emitting pixels 6 have the second light-emitting pixel size or a light-emitting pixel size that is larger than the first light-emitting pixel size. The first light-emitting pixels 4 have a rectangular or square design. The second light-emitting pixels 6 partly have a rectangular or square design and partly have other angular shapes with parallel sides. Thus installation space problems for the optical system used are prevented as well.

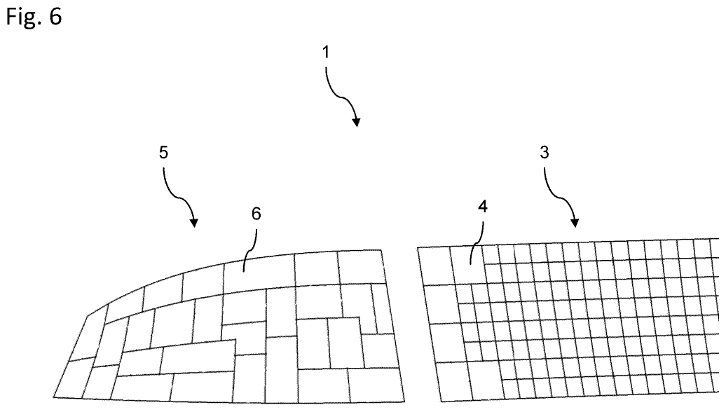

In FIG. 6, a lighting system 1 according to a fifth exemplary embodiment of the invention is shown schematically in a top view. The lighting system 1 has a first lighting device 3 with a plurality of first light-emitting pixels 4 and a second lighting device 5 with a plurality of second light-emitting pixels 6. The first light-emitting pixels 4 and the second light-emitting pixels 6 are each arranged in a grid. The second lighting device 5 also has a curvature about the vertical axis. Some of the first light-emitting pixels 4 have a first light-emitting pixel size that is smaller than a second light-emitting pixel size of the second light-emitting pixels 6, wherein the second light-emitting pixels 6 have different light-emitting pixel sizes, each of which is larger than the first light-emitting pixel size. In this exemplary embodiment, another part of the first light-emitting pixels 4, which is arranged adjacent to the second light-emitting pixels 6, has the second light-emitting pixel size. The first light-emitting pixels 4 have a rectangular or square design. The second light-emitting pixels 6 partly have a rectangular design and partly have other angular shapes with parallel sides. Thus installation space problems for the optical system used are prevented as well.

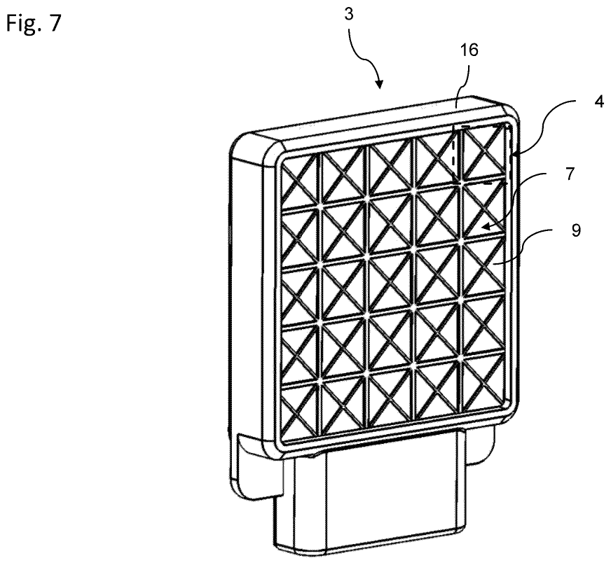

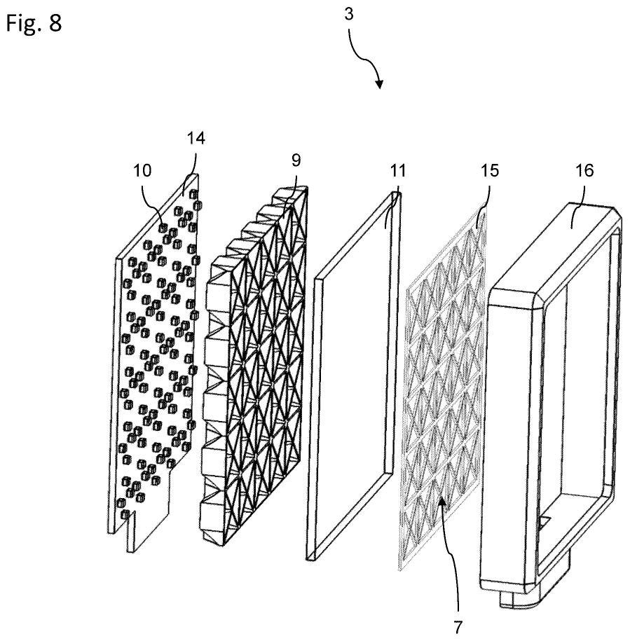

In FIGS. 7 and 8, a first lighting device 3 according to an exemplary embodiment of the invention is shown schematically in different views. The first lighting device 3 has a printed circuit board 14 on which several light-emitting diodes 10 are arranged as SMD components. A reflector element 9 is arranged in front of the printed circuit board 14. An optical layer 11 is arranged in front of the reflector element 9. An optional grid mask 15 may be arranged in front of the optical layer 11. A housing frame 16 is provided to delimit and protect the components of the first lighting device 3.

The second lighting device 5 preferably has the same elements as the first lighting device 3, which are preferably arranged in the same way with the exception of the light-emitting pixel sizes. Accordingly, the second lighting device 5 preferably has a printed circuit board 14 on which several light-emitting diodes 10 are arranged as SMD components. A reflector element 9 is arranged in front of the printed circuit board 14. An optical layer 11 is arranged in front of the reflector element 9. An optional grid mask 15 may be arranged in front of the optical layer 11. A housing frame 16 is preferably provided to delimit and protect the components of the second lighting device 5.

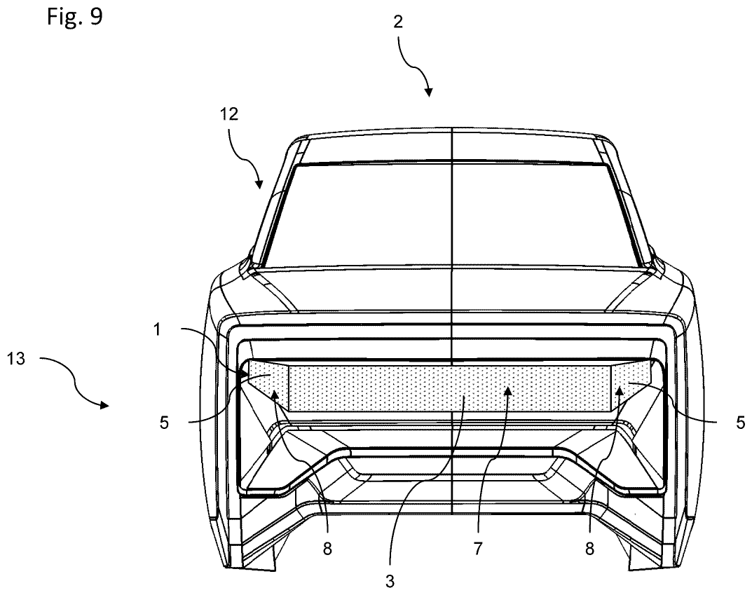

FIG. 9 schematically shows a rear view of a motor vehicle 2 according to an exemplary embodiment of the invention. The motor vehicle 2 has a vehicle front 12, which is predominantly concealed in this view, and a vehicle rear 13. A lighting system 1 according to the invention is arranged at the vehicle rear 13. The first lighting device 3 of the lighting system 1 is arranged centrally on the vehicle rear 13 and extends over a predominant part of the vehicle rear width of the vehicle rear 13. A second lighting device 5 of the lighting system 1 is arranged on each side of the first lighting device 3. In particular, a first emitting surface 7 of the first lighting device 3 and a second emitting surface 8 of each of the second lighting devices 5 can be seen from the lighting system 1.

### LIST OF REFERENCE NUMERALS

1 lighting system
2 motor vehicle
3 first lighting device
4 first light-emitting pixel
5 second lighting device
6 second light-emitting pixel
7 first emitting surface
8 second emitting surface
9 reflector element
10 light-emitting diode
11 optical layer
12 vehicle front
13 vehicle rear
14 printed circuit board
15 grid mask
16 housing frame

The above description is that of current embodiment of the invention. Various alterations and changes can be made without departing from the spirit and broader aspects of the invention. This disclosure is presented for illustrative purposes and should not be interpreted as an exhaustive description of all embodiments of the invention or to limit the scope of the claims to the specific elements illustrated or described in connection with these embodiments. Any reference to elements in the singular, for example, using the articles “a,” “an,” “the,” or “said,” is not to be construed as limiting the element to the singular.

1. A lighting system for a motor vehicle, the lighting system comprising:
a first lighting device including a plurality of separately controllable first light-emitting pixels, at least one of the first light-emitting pixels defining a first pixel size; and
two second lighting devices, each of which are disposed laterally relative to the first lighting device and each of which have a plurality of separately controllable second light-emitting pixels, wherein at least one of the second light-emitting pixels defines a second pixel size which is larger than the first pixel size of the at least one of the first light-emitting pixels.

2. The lighting system of claim 1, wherein the at least one of the second light-emitting pixels has a pixel height which is at least twice as large as a pixel height of the at least one of the first light-emitting pixels.

3. The lighting system of claim 1, wherein the at least one of the second light-emitting pixels has a pixel width which is at least twice as large as a pixel width of the at least one of the first light-emitting pixels.

4. The lighting system of claim 1, wherein at least two of the second light-emitting pixels define dissimilar pixel heights or dissimilar pixel widths.

5. The lighting system of claim 1, wherein greater than 50% of the first light-emitting pixels have the first pixel size.

6. The lighting system of claim 1, wherein a further one of the second light-emitting pixels has the first pixel size.

7. The lighting system of claim 1, wherein a further one of the first light-emitting pixels has a third pixel size, wherein the third pixel size is larger than the first pixel size.

8. The lighting system of claim 1, wherein the second pixel size is at least four times that of the first pixel size.

9. The lighting system of claim 1, wherein the first lighting device have a first emitting surface that is curved by a maximum of 20° about a vertical axis.

10. The lighting system of claim 1, wherein the second lighting devices each have a second emitting surface that is curved by at least 20° about a vertical axis.

11. The lighting system of claim 1, wherein the first light-emitting pixels and the second light-emitting pixels have a reflector, a light emitting diode, and a light-transmitting optical layer.

12. The lighting system of claim 11, wherein the first light-emitting pixels and the second light-emitting pixels have a plurality of light-emitting diodes with different colors.

13. The lighting system of claim 11, wherein the optical layer comprises a diffuser film or a diffuser plate.

14. A motor vehicle comprising a vehicle front and a vehicle rear, wherein the lighting system of claim 1 is arranged on the vehicle front or the vehicle rear, wherein the first lighting device extends over at least a partial area of the vehicle front or the vehicle rear, and wherein the two second lighting devices are each arranged at one side of the first lighting device and each extend over partial areas of two vehicle sides of the motor vehicle.
